(19) United States
(12) Patent Application Publication
(10) Pub. No.: US 2007/0012666 A1
(43) Pub. Date: Jan. 18, 2007

(54) Laser trimmed semiconductor device and a method of manufacturing the same

(75) Inventor: Michio Yamashita, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/402,893

(22) Filed: Apr. 13, 2006

(30) Foreign Application Priority Data
Jul. 12, 2005 (JP) 2005-203229

(51) Int. Cl. B23K 26/38; H01C 17/242

(52) U.S. Cl. 219/121.69; 338/195

(57) ABSTRACT

A method of laser trimming a semiconductor device having a plurality of thin film resistors is disclosed. The method includes choosing a linear trimming direction in which a linearly polarized laser beam will be applied to the thin film resistors to thereby create trim cuts in the thin film resistors. The linear trimming direction is chosen to ensure that the linearly polarized laser beam forms complete trim cuts in the thin film resistors and such that strip-like uncut parts are unlikely to be generated. The method also includes forming trim cuts in the thin film resistors by applying the linearly polarized laser beam to the thin film resistors in the linear trimming direction only. Accordingly, it is possible to reduce the generation of strip-like uncut parts when the thin film resistor is laser-trimmed using the linearly polarized laser beam.

### CROSS REFERENCE TO RELATED APPLICATION

This application is based upon and claims the benefit of priority of Japanese Patent Application No. 2005-203229 filed on Jul. 12, 2005, the content of which is incorporated herein by reference.

### BACKGROUND OF THE INVENTION

1. Field of the Invention

The present invention relates generally to laser trimming and, more specifically, relates to a laser trimmed semiconductor device and a method of manufacturing the same.

2. Description of the Related Art

Laser trimming is used for trimming thin film resistors of an IC chip (see U.S. Pat. No. 5,081,439 and Japanese Patent No. 2,618,139 for example). Specifically, as shown in FIGS. 10A and 10B, in the case of an IC chip, a thin film resistor 202 and electrodes 205 are formed on a silicon substrate 200. An insulation film 201 is interposed between the thin film resistor 202 and the silicon substrate 200. A protective film 204 can also be disposed over the thin film resistor 202 on a side opposite to the insulation film 201. The thin film resistor 202 is trimmed by irradiating it with a laser beam to form a trim cut 203. The trim cut 203 has an L-shape defined by a first line segment 203a extending in the X-direction and a second line segment 203b extending in the Y-direction.

Laser trimming can be performed using a linearly polarized laser beam. However, the cutting condition of the laser beam may be different between the X- and Y-directions, and strip-like uncut parts 210 may be generated in one of the directions as shown in FIG. 11. For example, in the embodiment shown in FIG. 11, a greater number of strip-like uncut parts 210 are generated when cutting in the X-direction as compared to cutting in the Y-direction. When such strip-like uncut parts 210 are generated the strip-like uncut parts 210 may be subsequently broken, which can result in defects of the IC chip.

The magnitude of laser energy can be increased to reduce the occurrence of strip-like uncut parts 210 during trimming. However, increasing the laser energy may cause damage to the protective film 204 of the IC chip because the film 204 may not withstand the increased heat generated during trimming.

Accordingly, there remains a need for an improved method of laser trimming a thin-film resistor in which strip-like uncut parts are less likely to be created.

### SUMMARY OF THE INVENTION

According to the teachings of the present invention, it is possible to perform laser trimming with a linearly polarized laser beam in a manner in which strip-like uncut parts are unlikely to be generated.

In one aspect, a method of laser trimming a semiconductor device having a plurality of thin film resistors is disclosed. The method includes choosing a linear trimming direction in which a linearly polarized laser beam will be applied to the thin film resistors to thereby create trim cuts in the thin film resistors. The linear trimming direction is chosen to ensure that the linearly polarized laser beam forms complete trim cuts in the thin film resistors and such that strip-like uncut parts are unlikely to be generated. The method also includes forming trim cuts in the thin film resistors by applying the linearly polarized laser beam to the thin film resistors in the linear trimming direction only. Accordingly, it is possible to reduce the generation of strip-like uncut parts when the thin film resistor is laser-trimmed using the linearly polarized laser beam.

In another aspect, a method of laser trimming a semiconductor device having a thin film resistor is disclosed. The method involves the step of providing the thin film resistor on a silicon substrate with an insulation film interposed between the thin film resistor and the silicon substrate. The method also involves providing a plurality of LOCOS oxide films between the insulation film and the silicon substrate to thereby define a plurality of reflecting interfaces at interfaces of the LOCOS oxide films and the silicon substrate. The LOCOS oxide films each extend in a direction that is parallel to a linear trimming direction. In addition, the method involves applying the linearly polarized laser beam so as to reflect the linearly polarized laser beam from at least one of the reflecting interfaces toward the thin film resistor to thereby form a trim cut in the thin film resistor. As such, the thin film resistor can be fused and cut to allow a trim cut to be easily formed in a direction in which strip-like uncut parts are unlikely to be generated.

In still another aspect, a method of laser trimming a semiconductor device with a laser apparatus is disclosed. The semiconductor device includes a thin film resistor, and the laser apparatus has a polarizer and emits a linearly polarized laser beam. The method includes the step of applying the linearly polarized laser beam in a first linear trimming direction to thereby form a first trim cut in the thin film resistor. The method also includes rotating the polarizer about an optical axis of the linearly polarized laser beam. In addition, the method includes applying the linearly polarized laser beam in a second linear trimming direction to thereby form a second trim cut in the thin film resistor. As such, it is possible to reduce the generation of strip-like uncut parts when the thin film resistor is laser-trimmed using the linearly polarized laser beam.

In a further aspect, a semiconductor device is disclosed which includes a silicon substrate and a plurality of thin film resistors. Each of the thin film resistors includes at least one trim cut formed by a linearly polarized laser beam. Also, all of the trim cuts are parallel to each other and extend in a linear trimming direction. Furthermore, the linear trimming direction is chosen to ensure that the linearly polarized laser beam forms complete trim cuts. Accordingly, the thin film resistors are unlikely to include strip-like uncut parts.

### BRIEF DESCRIPTION OF THE DRAWINGS

FIG. 1 is a plan view of an IC chip in a first embodiment of the invention;

FIG. 2 is a longitudinal sectional view taken along the line II-II in FIG. 1;

FIG. 3 is a plan view of an IC chip for comparison to FIG. 1;

FIG. 4 is a plan view of a thin film resistor to be laser-trimmed in an IC chip before trimming according to a second embodiment of the invention;

FIG. 5 is a longitudinal sectional view taken along the line V-V in FIG. 4;

FIG. 6 is a plan view of the thin film resistor in the IC chip during laser trimming;

FIG. 7 is a longitudinal sectional view of the IC chip during laser trimming associated with the line VII-VII in FIG. 6;

FIG. 8 is a perspective view of an IC chip during laser trimming according to a third embodiment of the invention;

FIG. 9 is a perspective view of the IC chip during laser trimming according to the third embodiment of the invention;

FIGS. 10A and 10B show a plan structure and a longitudinal sectional structure of an IC chip for explaining the prior art; and

FIG. 11 is a plan view of the IC chip shown in FIGS. 10A and 10B.

### DESCRIPTION OF THE PREFERRED EMBODIMENTS

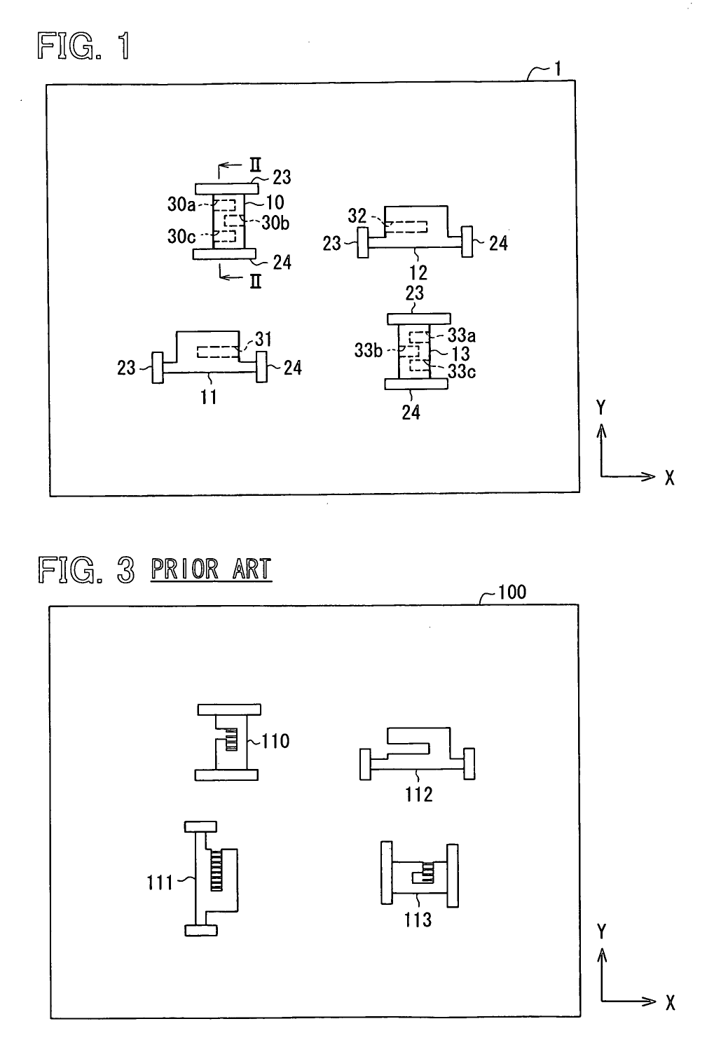

As shown in FIG. 1 an IC chip 1 is illustrated with a plurality of thin film resistors, namely a first thin film resistor 10, a second thin film resistor 11, a third thin film resistor 12, and a fourth thin film resistor 13. Each of the thin film resistors are to be laser-trimmed in a manner to be described in greater detail below. The portions of the resistors 10, 11, 12, 13 shown with broken lines represent areas that will be laser-trimmed as discussed in greater detail below.

The thin film resistors 10, 11, 12, 13 are provided in a pattern layout. The directions of the two orthogonal axes constitute X- and Y-directions. It will be appreciated that the IC chip 1 could include any number of thin film resistors 10, 11, 12, 13 without departing from the scope of the present disclosure.

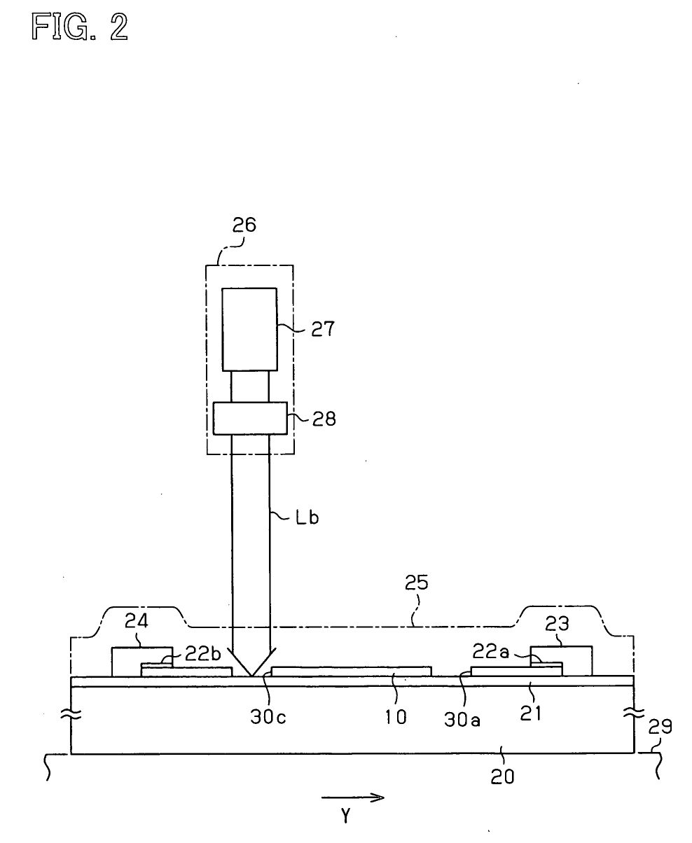

The first thin film resistor 10 has a rectangular shape before it is trimmed. Also, as shown in FIG. 2, the first thin film resistor 10 is formed on a top surface of a silicon substrate 20 with an insulation film 21 (e.g., SiO₂ film) interposed between the resistor 10 and the substrate 20. Aluminum electrodes 23, 24 are disposed at opposite ends of the thin film resistor 10 on the insulation film 21. Barrier metal layers 22a, 22b are interposed between the electrodes 23, 24 and the resistor 10. Furthermore, the thin film resistor 10 is coated with a surface protection film 25 (e.g., SiO₂ film).

Referring back to FIG. 1, the fourth thin film resistor 13 has a rectangular shape similar to the first thin film resistor 10. The second and third thin film resistors 11, 12 to be laser-trimmed are each shaped like a top hat. Similar to the first thin film resistor 10, the second, third, and fourth thin film resistors 11, 12, 13 each include aluminum electrodes 23, 24 on both ends.

As shown in FIG. 2, the wafer (i.e., the silicon substrate 20) is supported by an X-Y table 29, and the wafer can be moved as a result of movement of the X-Y table 29 in a horizontal plane (i.e., back and forth and to the left and right).

A laser apparatus 26 is provided above the X-Y table 29 and above the wafer. The laser apparatus 26 has a linear polarizer 28 in addition to a laser oscillator 27. The linear polarizer 28 may be a polarizing plate. The linear polarizer 28 is disposed such that the emitted laser beam travels through the polarizer in a known manner.

During laser trimming operations, a laser beam (labeled “Lb” in FIG. 2) output by the laser oscillator 27 passes through the linear polarizer 28 and is projected on at least one of the thin film resistors 10, 11, 12, 13. In the embodiment shown in FIG. 2, the laser beam Lb is shown projected onto the first thin film resistor 10. As will be discussed below, the laser beam Lb can be projected onto the second, third, and/or fourth thin film resistors 11, 12, 13 as well.

Trimming is performed (i.e., the laser beam is projected onto the thin film resistor 10) while measuring the characteristic resistance values of the resistor 10. In one embodiment, the resistance values of the resistor 10 are measured by operatively connecting a first probe to a first pad (omitted in the illustration) that is integrally connected to the aluminum electrode 23, and by operatively connecting a second probe to a second pad (omitted in the illustration) that is integrally connected to the aluminum electrode 24.

Each of the thin film resistors 10, 11, 12, 13 is trimmed in only one linear direction so as to be parallel to each other. For instance, in the embodiment shown in FIG. 1, each of the thin film resistors 10, 11, 12, 13 are trimmed in the X-direction. Specifically, trim cuts 30a, 30b, 30c, 31, 32, 33a, 33b, 33c are formed in the thin film resistors 10, 11, 12, 13 during trimming operations. The X-direction was chosen as the trimming direction to ensure that the linearly polarized laser beam Lb forms more complete trim cuts 30a, 30b, 30c, 31, 32, 33a, 33b, 33c in the thin film resistors 10, 11, 12, 13. As such, strip-like uncut parts are unlikely to be generated in the thin film resistors 10, 11, 12, 13.

More particularly, the laser beam Lb is projected on the first thin film resistor 10, and laser trimming is performed linearly in the X-direction to form the trim cuts 30a, 30b, 30c. The trim cuts 30a, 30b, 30c are disposed in spaced relationship to each other along the Y-direction such that the resistor 10 is serpentine-cut (zigzag-cut) after trimming. However, it will be appreciated that the resistor 10 could include any suitable number of trim cuts and that the trim cuts could be formed in any suitable pattern without departing from the scope of the present disclosure.

Similarly, the trimming direction of the second thin film resistor 11 is also the X-direction. Specifically, a linear trim cut 31 extending in the X-direction is formed as a result of trimming, and ultimately the second thin film resistor 11 is single-cut. However, it will be appreciated that the second thin film resistor 11 could include any number of trim cuts formed in any suitable pattern without departing from the scope of the present disclosure.

Likewise, the trimming direction of the third thin film resistor 12 is also the X-direction. Specifically, a linear trim cut 32 extending in the X-direction is formed as a result of trimming, and ultimately the third thin film resistor 12 is single-cut. However, it will be appreciated that the second thin film resistor 12 could include any number of trim cuts formed in any suitable pattern without departing from the scope of the present disclosure.

In addition, the trimming direction of the fourth thin film resistor 13 is also the X-direction. Specifically, linear trim cuts 33a, 33b, 33c extending in the X-direction are formed as a result of trimming. The trim cuts 33a, 33b, 33c are disposed in spaced relationship to each other along the Y-direction such that the resistor 13 is serpentine-cut (zigzag-cut). However, it will be appreciated that the resistor 13 could include any suitable number of trim cuts and that the trim cuts could be formed in any suitable pattern without departing from the scope of the present disclosure.

The cutting condition of the laser beam Lb depends on the angle at which the linear polarizer 28 is set in the laser apparatus 26. As such, strip-like uncut parts are formed when trimming in one of the X- and Y-directions and more complete trim cuts are formed when trimming in the other of the X- and Y-directions. Accordingly, the trimming direction should be chosen so as to avoid forming strip-like uncut parts and so as to form more complete trim cuts. Thus, the X-direction was chosen as the trimming direction in the embodiment shown in FIG. 1 because the linearly polarized laser beam Lb is more likely to form complete trim cuts 30a, 30b, 30c, 31, 32, 33a, 33b, 33c when trimming in the X-direction.

Although the X-direction is the chosen trimming direction of FIGS. 1 and 2, it will be appreciated that the trimming direction could be any direction in which the trim cuts are more complete and in which strip-like uncut parts are unlikely to be formed. As such, the resistors 10, 11, 12, 13 will be of better quality because the resistors 10, 11, 12, 13 are unlikely to include strip-like uncut parts.

FIG. 3 is a plan view of an IC chip 100 presented for comparison with FIG. 1. The IC chip 100 includes a plurality of thin film resistors 110, 111, 112, 113 provided in a pattern layout. As shown, some of the trim cuts formed in the thin film resistors 110, 111, 112, 113 extend in the X-direction, and some of the trim cuts extend in the Y-direction. Those trim cuts that extend in the X-direction are more complete trim cuts. Those trim cuts that extend in the Y-direction include undesirable strip-like uncut parts.

On the contrary, the pattern layout and singular trimming direction of FIG. 1 allow the thin film resistors 10, 11, 12, and 13 to be trimmed without creating strip-like uncut parts. This is because the trim cuts 30a, 30b, 30c, 31, 32, 33a, 33b, 33c each extend in the X-direction, and no trim cuts extend in the Y-direction. That is, all trimming operations for the thin film resistors 10, 11, 12, 13 are performed in the X-direction only.

More specifically, as shown in FIG. 1, laser trimming is performed by applying the laser beam Lb to each of the thin film resistors 10, 11, 12, 13 present in the IC chip IC in the X-direction only. Accordingly, strip-like uncut parts are unlikely to be generated. That is, the first and fourth thin film resistors 10, 13 are rectangular in shape before trimming and are serpentine in shape after trimming. The second and third thin film resistors 11, 12 are shaped like top hats before trimming and include a single trim cut, respectively, after trimming. It is noted that the trim cuts are not made in an L-shape similar to those shown in FIG. 3 to thereby avoid creating strip-like uncut parts.

The layout of the IC chip 1 can be selected to allow for trimming in a single, linear direction. Preferably, the single, linear trimming direction is chosen such that more complete trim cuts in the thin film resistors and such that strip-like uncut part are unlikely to be generated.

Advantageously, the IC chip 1 is less likely to be defective because the strip-like uncut parts are unlikely to be generated. Furthermore, trimming can be performed at lower laser energy magnitudes. As such, the protective film 25 is unlikely to be damaged during trimming, and the thin film resistors 10, 11, 12, 13 can be more reliably protected by the protective film 25.

### Second Embodiment

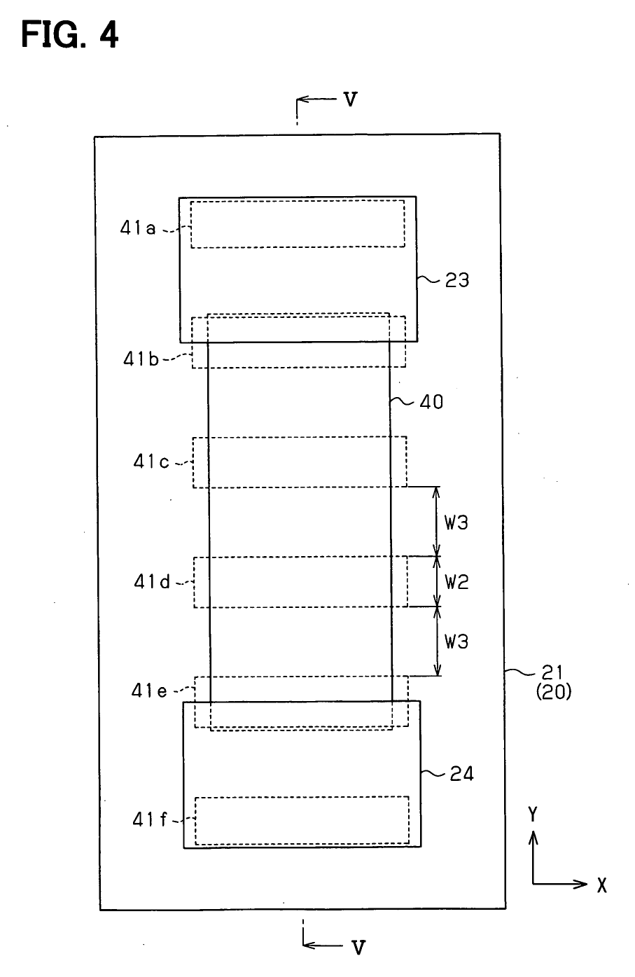

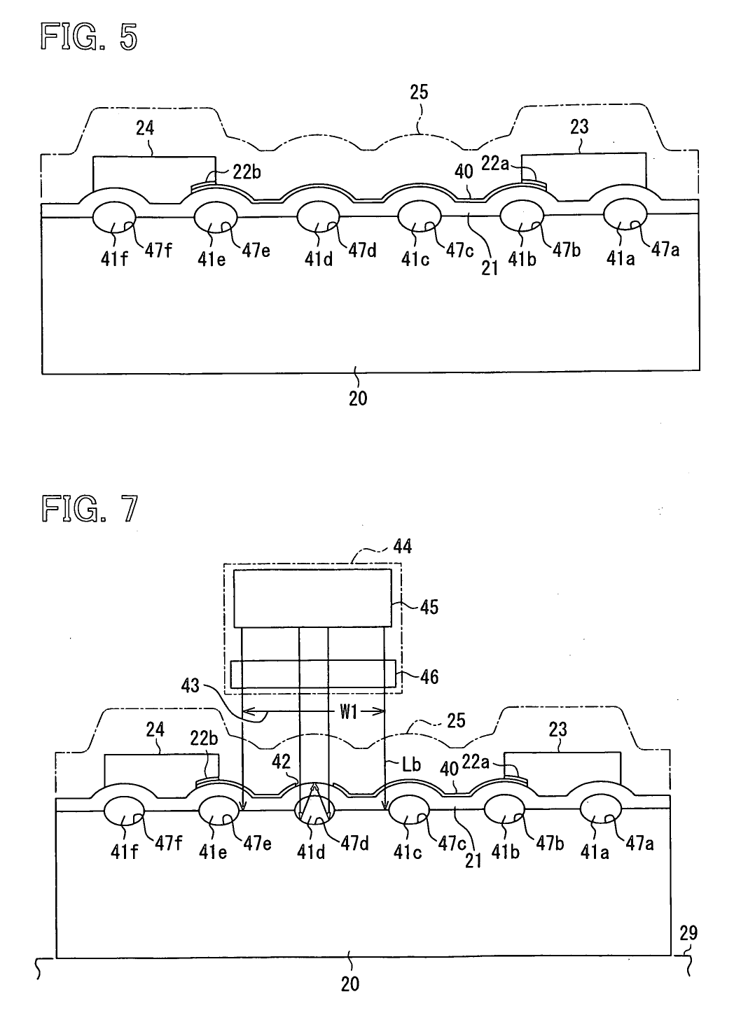

In the second embodiment illustrated in FIGS. 4, 5, 6, and 7, the IC chip includes an insulation film 21 formed on a silicon substrate 20. The thin film resistor 40 is formed on the insulation film 21 on a side opposite to the silicon substrate 20. The thin film resistor 40 has a rectangular shape in the plan view and extends in the Y-direction (see FIG. 4). Aluminum electrodes 23, 24 are formed over the insulation film 21. A first barrier metal layer 22a is interposed between the aluminum electrode 23 and one end of the thin film resistor 40, and a second barrier metal layer 22b is interposed between the aluminum electrode 24 and the opposite end of the thin film resistor 40. The electrodes 23, 24 are formed to extend above the thin film resistor 40 at both ends thereof. Also, the thin film resistor 40 is coated with a surface protective film 25 (e.g., SiO₂ film).

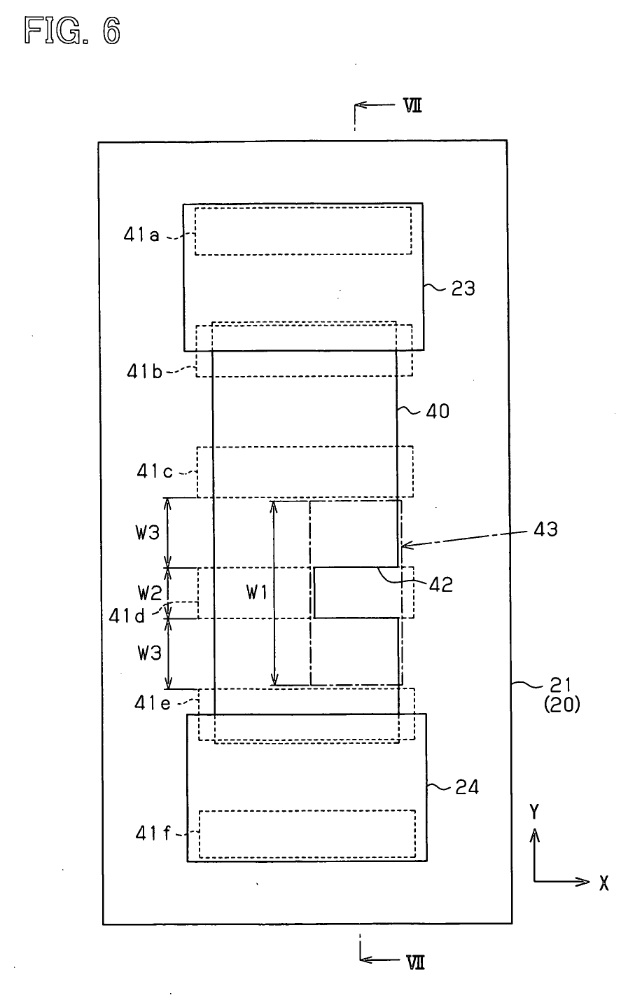

Further, the IC chip includes a plurality of LOCOS oxide films 41a, 41b, 41c, 41d, 41e, 41f. The LOCOS oxide films 41a-41f are disposed between the insulation film 21 and the silicon substrate 20. At least some of the LOCOS oxide films 41a-41f are disposed under the thin film resistor 40. The LOCOS oxide films 41a-41f are rectangular-shaped in their plan configuration and are disposed so as to extend in a linear trimming direction (see FIG. 4). Each of the LOCOS oxide films 41a-41f has a width W2 (see FIG. 6). Also, in the embodiment shown, the LOCOS oxide films 41a-41f are disposed in spaced relationship to each other at a distance W3 in the Y-direction. Furthermore, each of the LOCOS oxide films 41a-41f extends in the X-direction such that the LOCOS oxide films 41a-41f are parallel to each other. However, it will be appreciated that the LOCOS oxide films 41a-41f could extend in any suitable linear direction without departing from the scope of the present disclosure. In the embodiment shown, the LOCOS oxide films 41a-41f extend in the X-direction (i.e., the trimming direction) because it has been predetermined that such a trimming direction is unlikely to generate strip-like uncut parts during laser trimming as will be discussed.

Furthermore, a plurality of reflecting interfaces 47a, 47b, 47c, 47d, 47e, 47f is defined at the interface between the LOCOS oxide films 41a-41f and the silicon substrate 20. More specifically, in the embodiment shown, the LOCOS oxide films 41a-41f each include an arcuate bottom surface, which define the concave shaped reflecting interfaces 47a-47f. The reflecting interfaces 47a-47f are formed by bird's beaks at the bottom of the LOCOS oxide films 41a-41f. As will be discussed, the reflecting interfaces 47a-47f serve as concave mirrors for reflecting and converging light from the laser beam Lb onto the thin film resistor 40 to thereby trim the resistor 40.

As shown in FIG. 7, a laser apparatus 44 is provided for lasertrimming. The laser apparatus 44 is equipped with a laser oscillator 45 and a linear polarizer 46. The linear polarizer 46 is disposed such that the emitted laser beam travels through the polarizer 46 in a known manner.

During laser trimming operations (represented in FIG. 7), the wafer (i.e., substrate 20) is irradiated with a laser beam (labeled “Lb”) that has exited the laser oscillator 45 and passed through the linear polarizer 46. The width of the region 43 that is irradiated by the laser beam Lb is labeled as W1 in FIGS. 6 and 7. In the embodiment shown, the linearly polarized laser beam Lb is projected and applied in the X-direction (i.e., the trimming direction) across a region 43. In the embodiment shown, the X-direction is chosen as the trimming direction because it is determined that strip-like uncut parts are unlikely to be generated. It will be appreciated, however, that the trimming direction could be any other suitable direction other than the X-direction without departing from the scope of the present disclosure. Application of the laser beam Lb forms a trim cut 42 in the thin film resistor 40.

A part of the laser beam Lb travels through the surface protection film 25 (e.g., SiO₂), through the thin film resistor 40, and through the insulation film 21 (e.g., SiO₂). The laser beam Lb is then transmitted through at least one of the LOCOS oxide films (e.g., film 41d) and reflected from the reflecting interface 47d back toward the thin film resistor 40. When the trimming window (i.e., a width of trimming energy over which a favorable cut can be achieved) is small, a lens effect (i.e., a converging effect) occurs on the laser beam Lb by the reflecting interface 47d back toward the thin film resistor 40, and the reflected laser beam Lb converges on the thin film resistor 40 to thereby form the trim cut 42 in the thin film resistor 40. It will be appreciated that a similar converging effect occurs in association with each of the reflecting interfaces 47a-47f when the laser beam Lb is applied thereto.

It will be appreciated that although the laser beam Lb is applied to the resistor 40 across the region 43, the laser beam Lb trims the resistor 40 in an area that is less than the entire region 43 (i.e., the trim cut 42). That is, only a localized region 42 directly above the LOCOS oxide film 41d is trimmed instead of the entire region 43 to which the laser beam Lb is applied.

As shown in FIG. 6, the relationship “W1>(2·W2+W3)” is satisfied. (As mentioned previously, W1 represents the width of the area irradiated by the laser beam Lb, W2 represents the width of the LOCOS oxide films 41a-41f, and W3 represents the distance (width) between adjacent LOCOS oxide films 41a-41f.) Because the relationship “W1>(2·W2+W3)” is satisfied, any one of the LOCOS oxide films 41a-41f will stay entirely in the region 43 (i.e., the width W1) irradiated with the laser beam Lb during trimming operations. Thus, even if there is a positional deviation of the laser beam in the Y-direction, the respective LOCOS oxide film 41a-41f will remain within the irradiated region 43 (i.e., the width W1).

Also, when the thin film resistor 40 is trimmed in only one direction (e.g., the X-direction), only the localized region (i.e., the trim cut 42) directly above the respective LOCOS oxide film 41a-41f will be cut even if the trimming window is small or the beam width is somewhat unstable.

Advantageously, the second embodiment disclosed above allows the thin film resistor 40 to be easily fused and cut to form a trim cut 42 in a direction in which strip-like uncut parts are unlikely to be generated.

### Third Embodiment

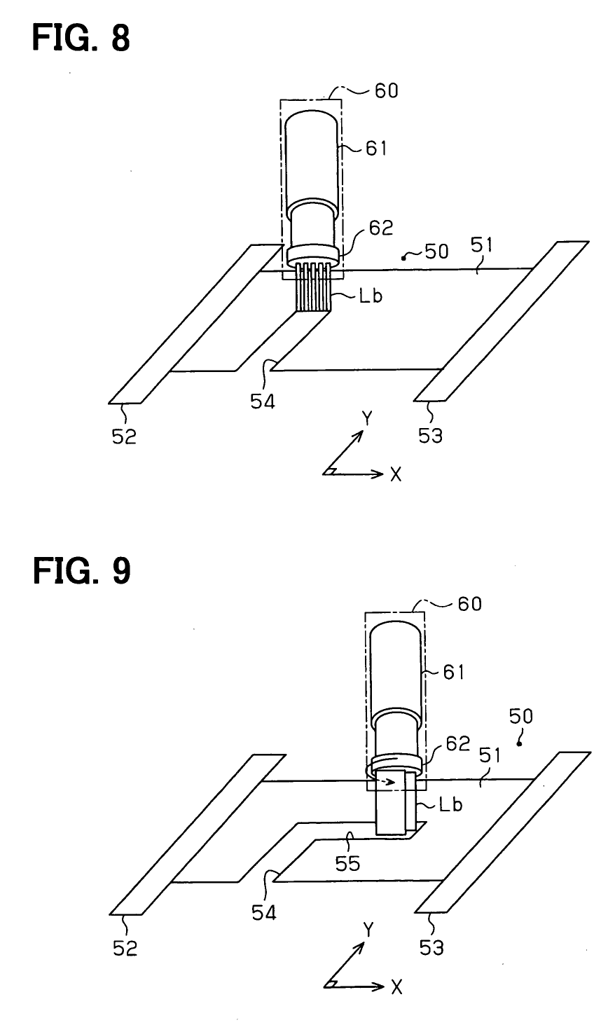

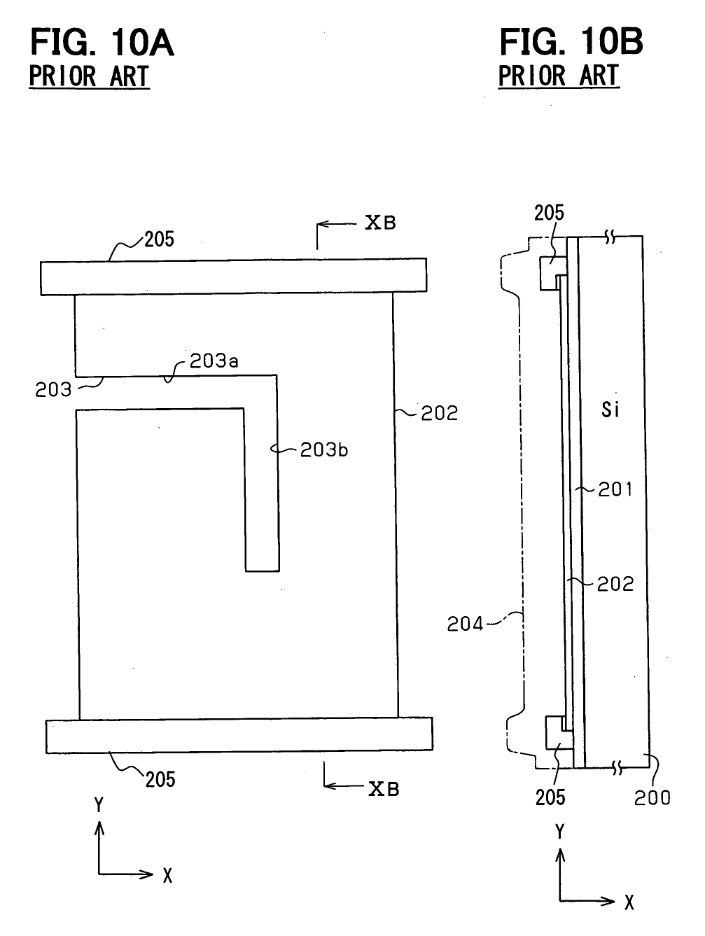

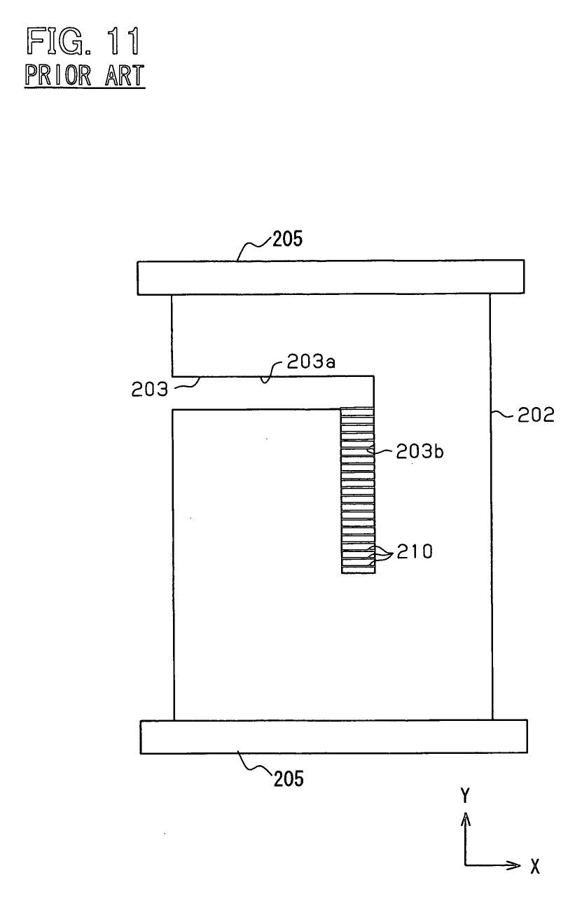

In a third embodiment illustrated in FIGS. 8 and 9, an IC chip 50 is illustrated that includes a thin film resistor 51. The thin film resistor 51 is rectangular-shaped in its plan configuration. In the embodiment shown, the thin film resistor 51 extends in the X-direction, and aluminum electrodes 52, 53 are formed on both ends of the thin film resistor 51.

A laser apparatus 60 is also illustrated. The laser apparatus 60 is equipped with a laser oscillator 61 and a linear polarizer 62. The linear polarizer 62 is disposed such that the emitted laser beam travels through the polarizer 62 in a known manner.

The thin film resistor 51 formed in the IC chip 50 is irradiated with a laser beam Lb that has exited the laser oscillator 61 and passed through the linear polarizer 62. The laser beam Lb can be applied in both the X- and Y-directions in the laser apparatus 60 in a manner to be described. In one embodiment, a table (not shown) on which the wafer is placed remains immobile during laser trimming (i.e., when the laser beam is applied). Further, the linear polarizer 62 of the laser apparatus 60 can be rotated about the optical axis of the laser beam and re-oriented as desired.

A pad (not shown) is integrally connected to each of the aluminum electrodes 52 and 53. Probes (not shown) can be operatively connected to the pads to thereby measure the resistance characteristics of the thin film resistor 51 during laser trimming.

As shown in FIG. 8, the laser trimming operation involves coarse trimming to form a first trim cut 54. Specifically, after passing through the linear polarizer 62, the laser beam Lb is applied on the thin film resistor 51 in a first linear trimming direction to form the first trim cut 54. Preferably, the first trimming direction is chosen such that strip-like uncut parts are unlikely to be generated. For instance, in the embodiment shown, the first trimming direction is in the Y-direction, and as such, the first trim cut 54 extends in the Y-direction. However, it will be appreciated that first trimming direction could be in any suitable direction without departing from the scope of the present disclosure.

Subsequently, as shown in FIG. 9, the laser beam Lb is applied to the thin film resistor 51 in a second linear trimming direction to form a second trim cut 55. In the embodiment shown, the second linear trimming direction is orthogonal to the first linear trimming direction. That is, the second linear trimming direction is the X-direction. A second trim cut 55 is formed to perform fine trimming. (It will be appreciated that FIG. 8 shows a state immediately preceding trimming in the second trimming direction (i.e., the X-direction), and FIG. 9 shows a state immediately after trimming in the second trimming direction (i.e., the X-direction).) Accordingly, the first and second trim cuts 54, 55 cooperate to define an L-shaped trim cut.

Immediately before trimming in the second trimming direction, the polarizer 62 is rotated ninety degrees (90°) about the optical axis of the laser beam (i.e., the direction of the polarizer 62 is turned ninety degrees (90°)). Once the polarizer 62 is rotated, trimming is performed in the second trimming direction (i. e., the X-direction). In one embodiment, the laser beam Lb is continuously applied while transitioning between trimming in the first trimming direction and trimming in the second trimming direction.

By rotating the polarizer 62 in an amount corresponding to the angular difference between the first and second trimming directions (e.g., 90°), trimming can be performed such that strip-like uncut parts are unlikely to be formed in either of the first or second trimming directions.

It will be appreciated that the laser application may be performed by moving the wafer (i.e., by moving the table) instead of moving the laser beam Lb. The polarizer 62 may be rotated when the trimming direction is changed during the application of the laser beam.

It will also be appreciated that although the polarizer 62 is rotated ninety degrees (90°) in the embodiment shown (i.e., in the case of an L-cut), the polarizer 62 can be rotated by any suitable angular amount other than ninety degrees (90°) to achieve any other suitably shaped cut. That is, the polarizer 62 may be rotated by any suitable angular amount that corresponds to the angular difference between the first trimming direction and the second trimming direction. As such, strip-like uncut parts are unlikely to be generated when trimming the resistor 51.

The present embodiment provides the following advantages. By rotating the polarizer 62 while transitioning between trimming in the first trimming direction and trimming in the second trimming direction, trimming can performed by applying the laser beam Lb in a direction in which strip-like uncut parts are unlikely to be generated. In the embodiment shown, for instance, by rotating the polarizer 62 ninety degrees (90°), strip-like uncut parts are unlikely to be formed in orthogonal directions (i.e., the X- and Y-directions). That is, trimming can be performed only in a direction in which strip-like uncut parts are unlikely to be generated. Thus, strip-like uncut parts are unlikely to be generated when the thin film resistor 51 is laser-trimmed using the linearly polarized laser beam Lb.

The present invention has been described in an illustrative manner. It is to be understood that the terminology, which has been used, is intended to be in the nature of words of description rather than of limitation. Many modifications and variations of the present invention are possible in light of the above teachings. Therefore, within the scope of the appended claims, the present invention may be practiced other than as specifically described.

What is claimed is:

1. A method of laser trimming a semiconductor device having a plurality of thin film resistors, the method comprising the steps of:
choosing a linear trimming direction in which a linearly polarized laser beam will be applied to the thin film resistors to thereby create trim cuts in the thin film resistors, wherein the linear trimming direction is chosen to ensure that the linearly polarized laser beam forms complete trim cuts in the thin film resistors; and
forming trim cuts in the thin film resistors by applying the linearly polarized laser beam to the thin film resistors in the linear trimming direction only.

2. A method of laser trimming a semiconductor device having a thin film resistor comprising the steps of:
providing the thin film resistor on a silicon substrate with an insulation film interposed between the thin film resistor and the silicon substrate;
providing a plurality of LOCOS oxide films between the insulation film and the silicon substrate to thereby define a plurality of reflecting interfaces at interfaces of the LOCOS oxide films and the silicon substrate, wherein the LOCOS oxide films each extend in a direction that is parallel to a linear trimming direction; and
applying the linearly polarized laser beam so as to reflect the linearly polarized laser beam from at least one of the reflecting interfaces toward the thin film resistor to thereby form a trim cut in the thin film resistor.

3. The method of laser trimming according to claim 2, wherein the LOCOS oxide films have an arcuate surface at the respective reflecting interface, and wherein the step of applying the linearly polarized laser beam involves converging the linearly polarized laser beam on the at least one of the thin film resistors to thereby form a trim cut in the at least one thin film resistor.

4. The method of laser trimming according to claim 2, wherein step of applying the linearly polarized laser beam involves applying the linearly polarized laser beam along at least one LOCOS oxide film in the trimming direction only.

5. A method of laser trimming a semiconductor device with a laser apparatus, wherein the semiconductor device includes a thin film resistor, and wherein the laser apparatus has a polarizer and emits a linearly polarized laser beam, the method comprising the steps of:
applying the linearly polarized laser beam in a first linear trimming direction to thereby form a first trim cut in the thin film resistor; and
rotating the polarizer about an optical axis of the linearly polarized laser beam; and
applying the linearly polarized laser beam in a second linear trimming direction to thereby form a second trim cut in the thin film resistor.

6. The method of laser trimming of claim 5, wherein the step of rotating the polarizer comprises rotating the polarizer in an amount corresponding to the angular difference between the first and second trimming directions.

7. The method of laser trimming of claim 5, wherein the linearly polarized laser beam is continuously applied while transitioning between trimming in the first trimming direction and trimming in the second trimming direction.

8. The method of laser trimming of claim 5, wherein the step of rotating the polarizer comprises rotating the polarizer approximately ninety degrees (90°) about the optical axis of the linearly polarized laser beam.

9. A semiconductor device comprising:
a silicon substrate; and
a plurality of thin film resistors, wherein each of the thin film resistors includes at least one trim cut formed by a linearly polarized laser beam, and wherein all of the trim cuts are parallel to each other and extend in a linear trimming direction, wherein the linear trimming direction is chosen to ensure that the linearly polarized laser beam forms complete trim cuts.
